(19) United States
(12) Patent Application Publication
(10) Pub. No.: US 2012/0299141 A1
(43) Pub. Date: Nov. 29, 2012

(54) AVALANCHE PHOTODIODE AND AVALANCHE PHOTODIODE ARRAY

(75) Inventors: Yoshifumi Sasahata, Tokyo (JP); Masaharu Nakaji, Tokyo (JP)

(73) Assignee: Mitsubishi Electric Corporation, Tokyo (JP)

(21) Appl. No.: 13/326,436

(22) Filed: Dec. 15, 2011

(30) Foreign Application Priority Data
May 27, 2011 (JP) 2011-118766

(51) Int. Cl. H01L 31/107

(52) U.S. Cl. 257/434; 257/438; 257/E31.063

(57) ABSTRACT

An avalanche photodiode including a semiconductor substrate of a first conductivity type, an avalanche multiplication layer, an electric field control layer, a light absorption layer, and a window layer wherein the layers are laid one on another in this order on a major surface of the semiconductor substrate, an impurity region of a second conductivity type in a portion of the window layer, and a straight electrode on the impurity region and connected to the impurity region, the straight electrode being straight as viewed in a plan view facing the major surface of the semiconductor substrate.

### BACKGROUND OF THE INVENTION

1. Field of the Invention

The present invention relates to an avalanche photodiode and an avalanche photodiode array which can realize an increased aperture ratio.

2. Background Art

Semiconductor light receiving devices include an avalanche photodiode having a light absorption layer and an avalanche multiplication layer. In an avalanche photodiode disclosed in Japanese Patent Laid-Open No. 62-033482, an electrode and a multiplication layer are adjacent to each other and, therefore, a high electric field can be easily applied to the multiplication layer. A recessed portion is therefore formed in the multiplication layer to suppress edge breakdown. Due to the formation of the recessed portion, however, the process is complicated and the device characteristics vary. On the other hand, an avalanche photodiode disclosed in Japanese Patent Laid-Open No. 2010-135360 has a structure in which an electrode and a multiplication layer are not adjacent to each other, and in which an electric field control layer is provided to suppress edge breakdown.

In a photodiode disclosed in Japanese Patent Laid-Open No. 2000-101130, a comb-type Schottky electrode is provided on an absorption layer. However, light is received by a restricted depletion region formed in the vicinity of the electrode and cannot be received at a position remote from the electrode, so that the aperture ratio is low. On the other hand, the avalanche photodiode can operate normally even at a distance of about 30 from the electrode and can have the aperture ratio increased in comparison with the Schottky type.

In a photodiode disclosed in Japanese Patent Laid-Open No. 2001-119004, a p-type electrode and an n-type electrode are disposed at opposite ends of a light receiving region on a substrate front surface. Therefore, if the light receiving area in this photodiode is increased, the p-type electrode and the n-type electrode are distanced apart from each other to increase the resistance therebetween, resulting in band degradation. Also, no p-type impurity region is provided; a mesa structure is formed by etching after forming a p-type impurity region. There is, therefore, an anxiety about the reliability of the device. Moreover, the chip area is increased because wiring connected in matrix form is provided apart from the light receiving region.

In a photodiode disclosed in Japanese Patent Laid-Open No. 2002-100796, a current is injected from a p-type electrode disposed at an end of a light receiving region. Therefore, if the light receiving area is increased, the electric field is not uniformly applied at a position remote from the p-type electrode, resulting in band degradation. Each of the photodiodes disclosed in Japanese Patent Laid-Open Nos. 2000-101130, 2001-119004, and 2002-100796 has no multiplication layer and no electric field control layer and, therefore, has no multiplication function.

Prevention by light blocking metal of a reduction in response speed due to a diffusion current component caused by incidence of signal light on a portion other than the light receiving portion (see, for example, Japanese Patent Laid-Open Nos. 2002-100796, 63-211686, and 3-276769) and collection of light in an aperture with light blocking metal (see, for example, Japanese Patent Laid-Open No. 2007-281144) have also been proposed.

### SUMMARY OF THE INVENTION

The p-type electrode in each of the conventional avalanche photodiodes is in ring form. The electrode in ring form, however, has a large area, so that the area by which incident light is blocked is increased and the aperture ratio is reduced. If the area of the impurity region connected to the electrode is increased, the aperture ratio can be increased. However, the electric field applied to the impurity region is weaker at a distance remote from the electrode, so that the band is reduced. Also, the amplification factor is not uniform in the surface, and neither is the light receiving sensitivity. Thus, with the conventional avalanche photodiode, there is a problem that the area of the impurity region cannot be increased above a certain value and, therefore, a high aperture ratio cannot be achieved. There is also a problem that in a case where a plurality of avalanche photodiodes with electrodes in ring form are arrayed, the aperture ratio is reduced.

In view of the above-described problems, an object of the present invention is to provide an avalanche photodiode and an avalanche photodiode array which can realize an increased aperture ratio.

According to the present invention, an avalanche photodiode includes: a semiconductor substrate of a first conductivity type; an avalanche multiplication layer, an electric field control layer, a light absorption layer, and a window layer which are laid one on another in this order on a major surface of the semiconductor substrate; an impurity region of a second conductivity type in a portion of the window layer; and a straight electrode on the impurity region and connected to the impurity region, the straight electrode being straight as viewed in a plan view facing the major surface of the semiconductor substrate.

The present invention makes it possible to realize an increased aperture ratio.

Other and further objects, features and advantages of the invention will appear more fully from the following description.

### BRIEF DESCRIPTION OF THE DRAWINGS

FIG. 1 is a top view of an avalanche photodiode according to a first embodiment of the present invention.

FIG. 2 is a sectional view taken along line I-II in FIG. 1.

FIG. 3 is an enlarged top view of a region A in FIG. 1.

The effects of the first embodiment will be described in comparison with a comparative example.

FIG. 4 is a top view of an avalanche photodiode according to the comparative example.

FIG. 5 is a diagram showing the relationship between the area of the p-type impurity region 8 and the aperture ratio according to the first embodiment of the present invention.

FIG. 6 is a diagram showing changes in the band with respect to the distance a between the straight p-side electrode and an outer end of the p-type impurity region according to the first embodiment of the present invention.

FIG. 7 is a top view of an avalanche photodiode according to a second embodiment of the present invention.

FIG. 8 is a top view of an avalanche photodiode according to a third embodiment of the present invention.

FIG. 9 is a top view of an avalanche photodiode according to a fourth embodiment of the present invention.

FIG. 10 is a sectional view taken along line I-II in FIG. 9.

FIG. 11 is an enlarged top view of a region A in FIG. 9.

FIG. 12 is an enlarged top view of a region B in FIG. 9.

FIG. 13 is a top view of an avalanche photodiode according to a fifth embodiment of the present invention.

FIG. 14 is a sectional view taken along line I-II in FIG. 13.

FIG. 15 is a sectional view taken along line III-IV in FIG. 13.

FIG. 16 is a top view of an avalanche photodiode according to a sixth embodiment of the present invention.

FIG. 17 is a top view of an avalanche photodiode according to a seventh embodiment of the present invention.

FIG. 18 is a top view of an avalanche photodiode array according to an eighth embodiment of the present invention.

### DETAILED DESCRIPTION OF THE PREFERRED EMBODIMENTS

An avalanche photodiode and an avalanche photodiode array according to the embodiments of the present invention will be described with reference to the drawings. The same components will be denoted by the same symbols, and the repeated description thereof may be omitted.

### First Embodiment

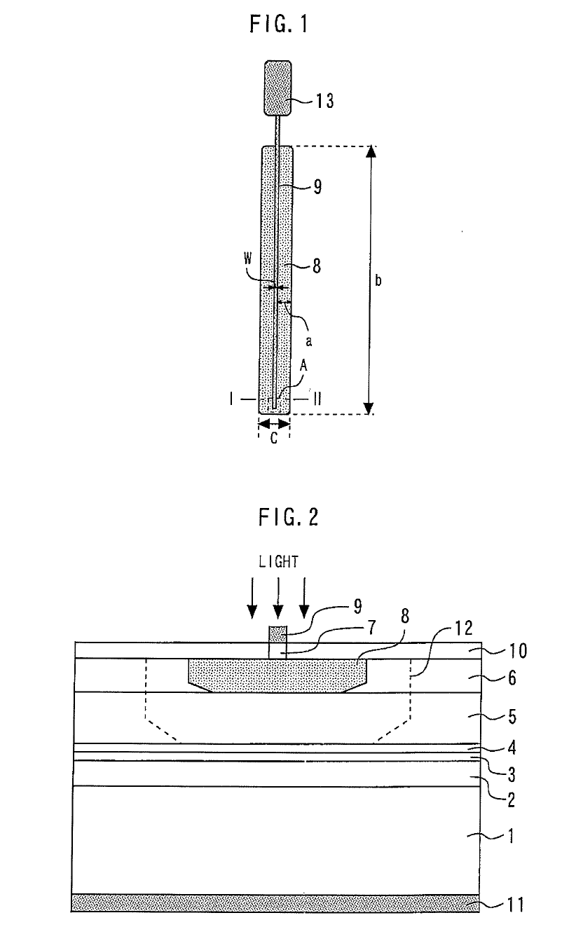

FIG. 1 is a top view of an avalanche photodiode according to a first embodiment of the present invention. FIG. 2 is a sectional view taken along line I-II in FIG. 1. An n-type InP layer buffer layer 2, an avalanche multiplication layer 3 formed of undoped AlInAs and having a thickness of 0.15 to 0.4 μm, a p-type InP electric field control layer 4 having a thickness of 0.03 to 0.06 μm, a light absorption layer 5 formed of undoped InGaAs and having a thickness of 2 to 3 μm, an undoped InP window layer 6 having a thickness of about 2 μm and an InGaAs contact layer 7 are laid one on another in this order on a major surface of an n-type InP substrate 1. A p-type impurity region 8 is provided in a portion of the undoped InP window layer 6.

The impurity concentration in the n-type InP substrate is about 5×10¹⁸ cm⁻³; the impurity concentration in the p-type InP electric field control layer 4 is 0.5 to 1×10¹⁸ cm⁻³; and the impurity concentration in the p-type impurity region 8 is 1×10¹⁹ to 1×10²⁰ cm⁻³.

A straight p-side electrode 9 formed of Ti/Au or the like is disposed on the p-type impurity region 8, with the InGaAs contact layer 7 interposed therebetween. The straight p-side electrode 9 is connected to the p-type impurity region 8. A surface protective film 10 formed of silicon nitride covers the undoped InP window layer 6. The thickness of the surface protective film 10 is ¼ of the wavelength λ of incident light. An n-side electrode 11 formed of AuGe/Au is connected to the back surface of the n-type InP substrate 1. Incident light is, for example, laser light having a wavelength of λ=1.55 μm.

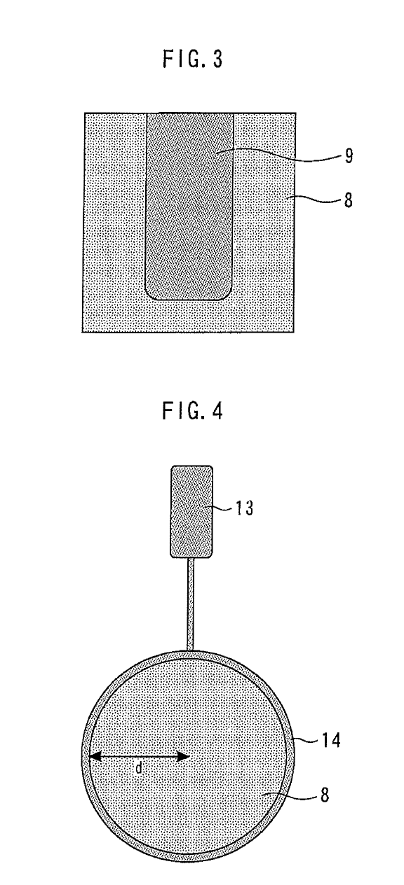

The straight p-side electrode 9 is straight, as viewed in a plan view facing the major surface of the n-type InP substrate 1. FIG. 3 is an enlarged top view of a region A in FIG. 1. The straight p-side electrode 9 is rounded at corners.

The width w of the straight p-side electrode 9 is 5 μm. The distance between the straight p-side electrode 9 and an outer end of the p-type impurity region 8 is 14.5 μm. The length b of the p-type impurity region 8 in the direction in which the straight p-side electrode 9 extends is longer than the width c of the p-type impurity region 8. The p-type impurity region 8 has a rectangular or corner-rounded rectangular shape as viewed in plan. The straight p-side electrode 9 extends along the longer sides of the p-type impurity region 8. The straight p-side electrode 9 is connected to an electrode pad 13 disposed on a region other than the p-type impurity region 8 in the undoped InP window layer 6. A connection portion between the straight p-side electrode 9 and the electrode pad 13 extends across the shorter side of the p-type impurity region 8.

A method of manufacturing the avalanche photodiode according to the present embodiment will be briefly described. The n-type InP layer buffer layer 2, the avalanche multiplication layer 3, the p-type InP electric field control layer 4, the light absorption layer 5, the undoped InP window layer 6 and the InGaAs contact layer 7 are first grown epitaxially on the n-type InP substrate 1 by using metal organic chemical vapor deposition (MOCVD) or the like.

Next, the p-type impurity region 8 is formed by diffusing Zn in a portion of the undoped InP window layer 6 to a depth reaching the light absorption layer 5. As a diffusion method, vapor phase diffusion, thermal diffusion or the like using a mask or the like is used. For example, in a case where thermal diffusion is performed, SiN film (not shown) is formed on the undoped InP window layer 6; an opening is formed in the SiN film on a region where the p-type impurity region 8 is to be formed; a diffusion source such as ZnO film (not shown) is formed in this opening and on the SiN film; and a heat treatment is performed for a predetermined time period, with the SiN film used as a mask. An impurity such as Cd or Be may be used in place of Zn.

After removal of SiN film and ZnO film, the InGaAs contact layer 7 is formed. The surface protective film 10 that functions as an antireflection film as well is thereafter formed on the surface of the undoped InP window layer 6 by plasma CVD or the like, and an opening is formed in the surface protective film 10 in a region where the straight p-side electrode 9 is to be formed, by using a combination of a photolithography technique and etching using hydrofluoric acid or the like. A photoresist (not shown) is provided on the surface protective film 10 and is patterned and an opening is formed in the photoresist in the opening of the surface protective film 10. Next, Ti/Au film is formed by electron beam (EB) deposition, and an unnecessary portion of this film is lifted off together with the photoresist to form the straight p-side electrode 9. At this time, the electrode pad 13 connected to the straight p-side electrode 9 is simultaneously formed on the surface protective film 10. Thereafter, the back surface of the n-type InP substrate 1 is polished and the n-side electrode 11 is formed. By the above-described process, the avalanche photodiode according to the present embodiment is manufactured.

The operation of the avalanche photodiode according to the present embodiment will be described. When a reverse bias voltage is applied from the outside so that the voltage on the n-side electrode 11 is pulse while the voltage on the straight A-side electrode 9 is minus, a depletion region 12 is formed. In this state, light of 1.55 μm, for example, is introduced. The light passes through the undoped InP window layer 6 and is absorbed in the light absorption layer 5 to generate electron-hole pairs (photocarrier). The generated electrons move to the n-side electrode 11 side, while the holes move to the straight A-side electrode 9 side. When the reverse bias voltage is sufficiently high, the electrons cause ionization in the avalanche multiplication layer 3 to generate new electron-hole pairs and act together with the newly generated electrons and holes to further cause ionization, thus causing avalanche multiplication whereby electrons and holes are multiplied in an avalanching manner.

The effects of the first embodiment will be described in comparison with a comparative example. FIG. 4 is a top view of an avalanche photodiode according to the comparative example. In the comparative example, an electrode 14 in ring form is provided so as to surround a circular p-type impurity region 8 having a radius d. The straight p-side electrode 9 in the present embodiment can be made smaller in size than the electrode 14 in ring form in the comparative example and therefore enables realization of an increased aperture ratio.

Also, the p-type impurity region 8 is formed so as to have a rectangular or corner-rounded rectangular shape to enable realization of an increased aperture ratio in comparison with the circular p-type Impurity region 8. Further, by forming the p-type impurity region 8 having a corner-rounded rectangular shape without angular corners, it is possible to avoid concentration of the electric field at corner portions of the p-type impurity region 8.

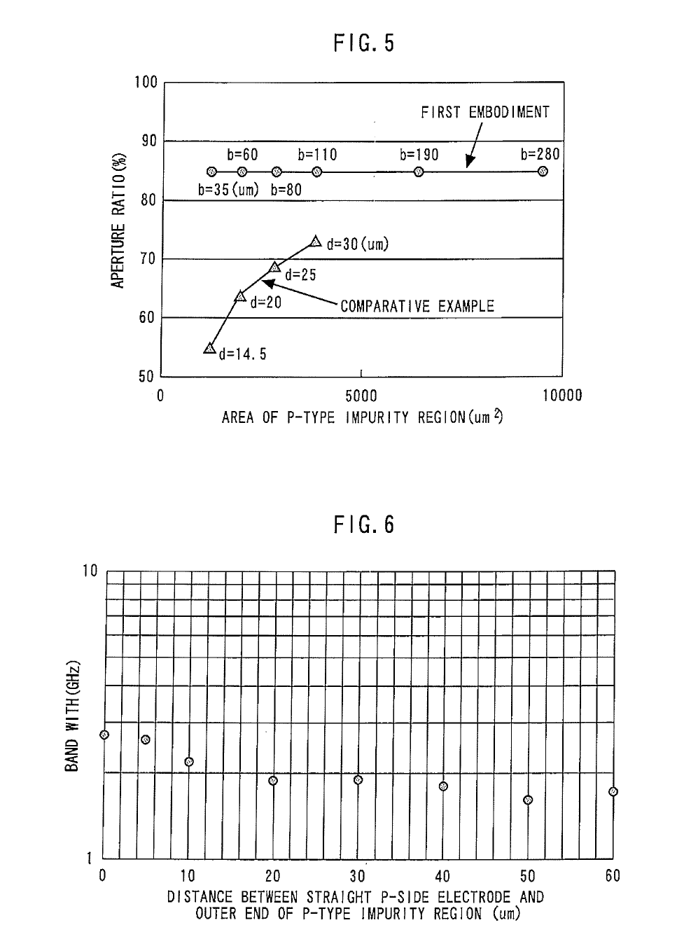

FIG. 5 is a diagram showing the relationship between the area of the p-type impurity region 8 and the aperture ratio according to the first embodiment of the present invention. The width w of the straight p-side electrode is 5 μm. In the comparative example, although the aperture ratio is increased if the area of the p-type impurity region 8 is increased, the aperture ratio is 55% when the radius d is 14.5 μm and the aperture ratio is 73% even when the radius d is 30 μm. On the other hand, in the first embodiment, if the length b of the straight p-side electrode 9 is changed, the area of the p-type impurity region 8 can be freely designed and a high aperture ratio of about 85% can be realized.

Also, it is possible to realize a high aperture ratio of about 80% or higher by setting to 20% or less the ratio of the width w of the straight p-side electrode 9 to the width c of the p-type impurity region 8 in a direction perpendicular to the direction in which the straight p-side electrode 9 extends. More specifically, when the width w is 5 μm and the ratio of the width w to the width c is about 151, the aperture ratio is about 85%. When the width w is 3 μm; the distance is 30 μl; and the ratio of the width w to the width c is about 5%, the aperture ratio is about 95%.

FIG. 6 is a diagram showing changes in the band with respect to the distance a between the straight p-side electrode 9 and an outer end of the p-type impurity region 8 according to the first embodiment of the present invention. If the distance a is increased, the band is reduced. However, band degradation can be limited if the distance is not larger than 30 μm. Also, non-uniformity of the multiplication factor in the surface occurs if the p-type impurity region 8 is increased. However, if the distance a is not larger than 30 μm, a uniform multiplication factor in the surface can be realized.

The connection portion between the straight p-side electrode 9 and the electrode pad 13 extends over and across only one portion of the p-type impurity region 8. Thus, concentration of the electric field at an end of the p-type impurity region 8 can be avoided.

The provision of the p-type InP electric field control layer 4 enables suppression of edge breakdown. An AlInAs electric field control layer may be used in place of the p-type InP electric field control layer 4.

### Second Embodiment

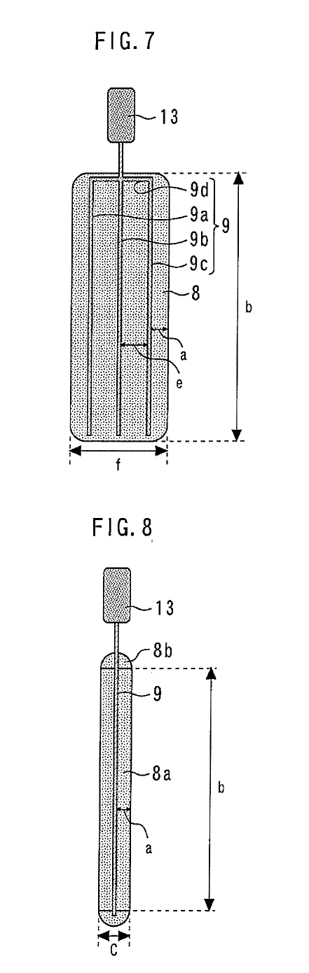

FIG. 7 is a top view of an avalanche photodiode according to a second embodiment of the present invention. The straight A-side electrode 9 has a plurality of straight electrode portions 9a, 9b, and 9c disposed in parallel with each other and an electrode portion 9d perpendicular to a plurality of the electrode portions 9a, 9b, and 9c and connected in common to these electrode portions.

The distance a is 20 μm. The distance e between each of adjacent pairs of electrode portions 9a and 9b, and 9b and 9c is 40 μm. The width w of each of the electrode portions 9a, 9b, and 9c is 5 μm. The p-type impurity region 8 has a rectangular or corner-rounded rectangular shape as viewed in plan. The length b of the p-type impurity region 8 is longer than the width f.

The effects of the second embodiment will be described. In the first embodiment, there is a limit to the width c of the p-type impurity region 8 because of use of the single straight p-side electrode 9 (the maximum of width c=2×30 μm+electrode width w because the distance a is 30 μm or less). In the second embodiment, since the plurality of electrode portions 9a, 9b, and 9c disposed in parallel with each other are used, the width f of the p-type impurity region 8 can be freely designed. It is, therefore, possible to increase the area of the p-type impurity region 8 while fixing the length b.

As described above with respect to the first embodiment, it is necessary that the p-type impurity region 8 exist within the range defined by 30 μm from the straight p-side electrode 9. It is, therefore, necessary to set the distance e between each of the adjacent pairs of electrode portions 9a and 9b, and 9b and 9c to 30×2=60 μm or less.

A connection portion between the electrode portion 9d and the electrode pad 13 extends over and across only one portion of the p-type impurity region 8. Thus, electric field concentration at an end of the p-type impurity region 8 can be avoided.

### Third Embodiment

FIG. 8 is a top view of an avalanche photodiode according to a third embodiment of the present invention. The p-type impurity region 8 has a rectangular region 8a in rectangular form as viewed in plan and two semicircular regions 8b respectively joined to shorter sides of the rectangular regions 8a. The semicircular regions 8b are thus joined to the rectangular region 8a to form the p-type impurity region 8 with no angular portions, thereby avoiding electric field concentration such as that at angular corners of the p-type impurity region 8.

### Fourth Embodiment

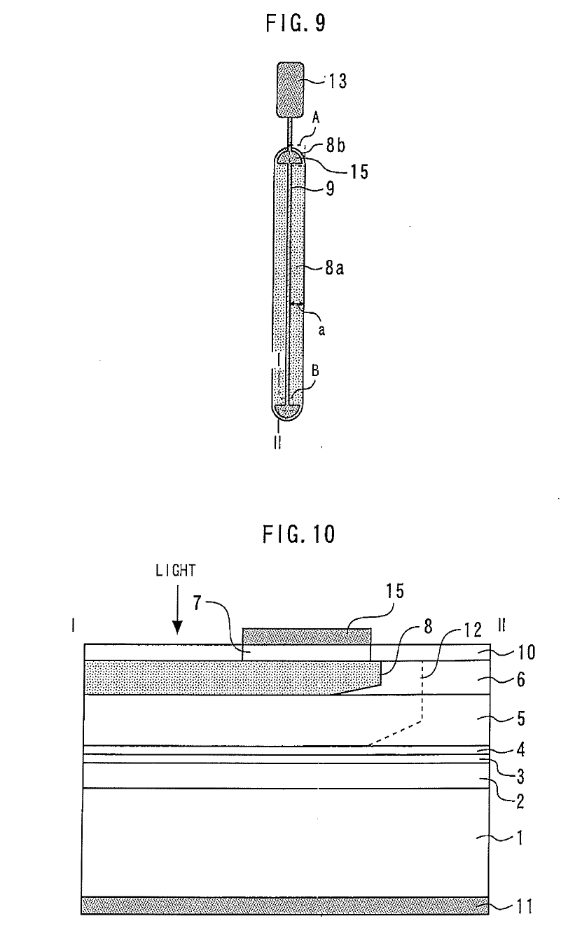

FIG. 9 is a top view of an avalanche photodiode according to a fourth embodiment of the present invention. FIG. 10 is a sectional view taken along line I-II in FIG. 9. Semicircular electrodes 15 are disposed on semicircular regions 8b. The semicircular electrodes 15 are connected to the straight p-side electrode 9.

In the fourth embodiment, the greater part of each semicircular region 8b other than an end portion of the semicircular region 8b is covered with the semicircular electrode 15 to block light, and a central portion of the rectangular region 8a is also covered with the straight p-side electrode 9 to block light, thus realizing two rectangular impurity regions where the band and the multiplication factor are uniform in the surface.

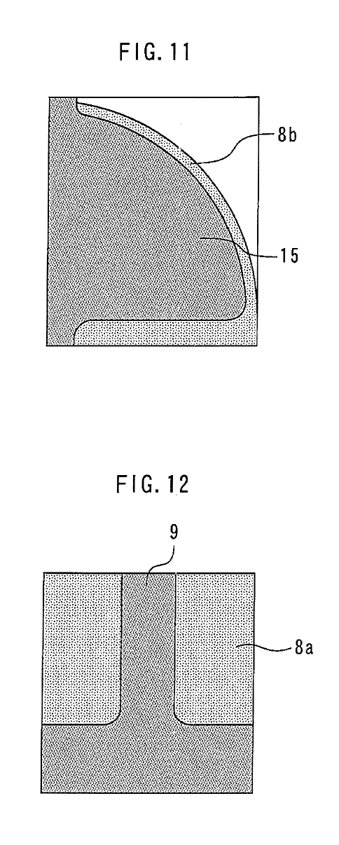

FIG. 11 is an enlarged top view of a region A in FIG. 9. FIG. 12 is an enlarged top view of a region B in FIG. 9. The straight p-side electrode 9 and the semicircular electrode 15 have no angular corner portions, thus avoiding electric field concentration at corner portions of the straight p-side electrode 9 and the semicircular electrode 15.

### Fifth Embodiment

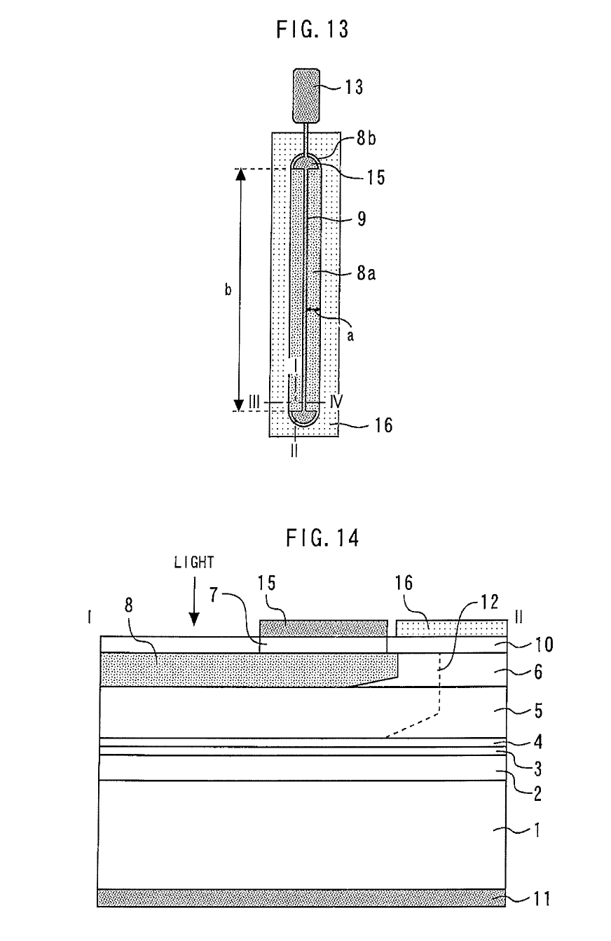

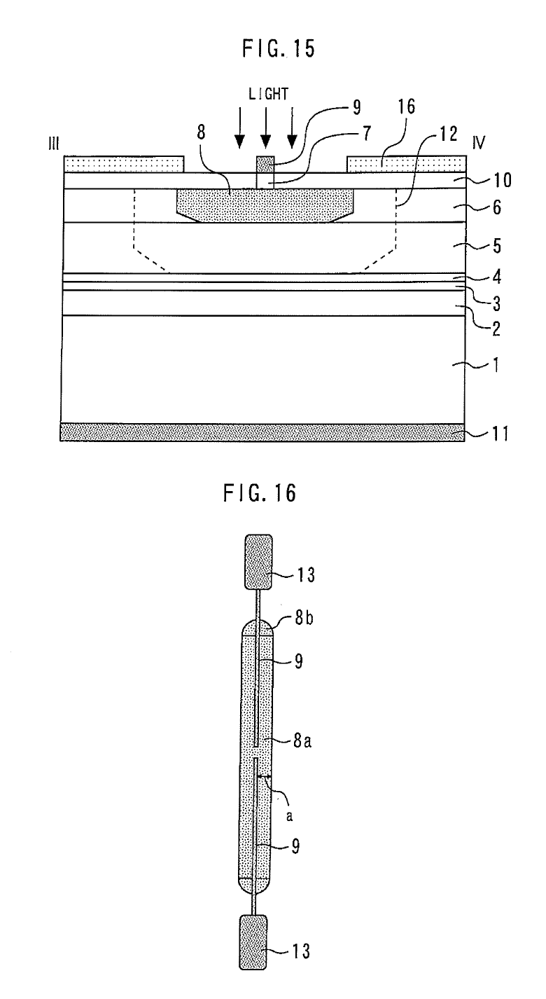

FIG. 13 is a top view of an avalanche photodiode according to a fifth embodiment of the present invention. FIG. 14 is a sectional view taken along line I-II in FIG. 13. FIG. 15 is a sectional view taken along line III-IV in FIG. 13.

Light blocking metal 16 is provided on the undoped InP window layer 6 except on the p-type impurity region 8. In this way, prevention of incidence of light on portions other than the p-type impurity region 8 provided as a light receiving portion is enabled. As a result, prevention of the occurrence of a non-uniformity of the multiplication factor at the end of the p-type impurity region 8 is enabled.

### Sixth Embodiment

FIG. 16 is a top view of an avalanche photodiode according to a sixth embodiment of the present invention. The straight p-side electrode 9 is divided into two portions separated at a center and respectively connected to different two electrode pads 13. The two electrode pads 13 are disposed on regions of the undoped InP window layer 6 other than the p-type impurity region 8. Connection portions between the two separate portions of the straight p-side electrode 9 and the two electrode pads 13 extend over and across only two portions of the p-type impurity region 8. In other respects, the construction is the same as that in the third embodiment.

By injecting currents from the two electrode pads 13, the electric field in the surface can be made uniform. Also, since the straight p-side electrode 9 is divided into two separated at a center, the aperture ratio can be increased.

### Seventh Embodiment

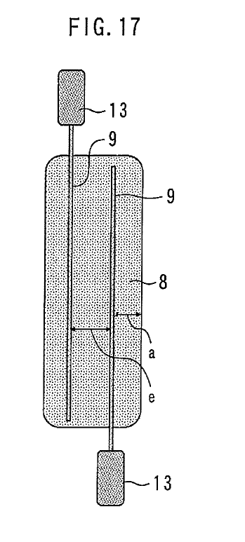

FIG. 17 is a top view of an avalanche photodiode according to a seventh embodiment of the present invention. Unlike the straight p-side electrode 9 in the sixth embodiment, two straight p-side electrodes 9 separate from each other are disposed parallel to each other. The distance e between the two straight p-side electrodes 9 is 40 μm. The same, effects as those of the sixth embodiment can be obtained in this way.

### Eighth Embodiment

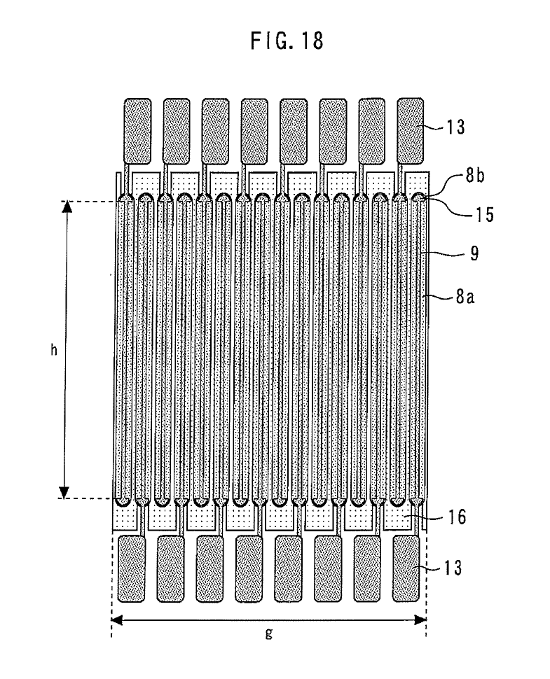

FIG. 18 is a top view of an avalanche photodiode array according to an eighth embodiment of the present invention. Sixteen avalanche photodiodes according to the fifth embodiment are disposed in an array, thus realizing a square light receiving region. For example, if the distance between each adjacent pair of p-type impurity regions 8 is 15.5 μm; the distance a is 21 μm; and the width w of the straight p-side electrodes 9 is 5 the width g of the light receiving region is (21 μm+21 μm+5 μm+15.5 μm)×16=1 mm. Further, the length h of the light receiving region may be set to 1 mm to realize a 1 mm square light receiving region. The aperture ratio in the light receiving region is 42 μm×100/(21 μm+21 μm+5 μm+15.5 μm)≈67%. If the area of each p-type impurity region 8 is increased, the aperture ratio of the entire device becomes higher. The same effects can be obtained by disposing a plurality of avalanche photodiodes according to one of the first to seventh embodiments in an array in a suitable way not limited to the example described above.

In each of the above-described first to eighth embodiments, the aperture ratio can be further increased by using a transparent electrode as the straight p-side electrode 9. For example, in a case where the straight p-side electrode 9 in the eighth embodiment is an ordinary electrode, the aperture ratio is 42 μm×100/(21 μm+21 μm+5 μm+15.5 μm)≈67%. In contrast, in a case where the straight p-side electrode 9 is a transparent electrode, the aperture ratio is increased to (21 μm+21 μm+5 μm)×100/(21 μm+21 μm+5 μm+15.5 μm)≈75%.

In each of the above-described first to eighth embodiments, it is preferable that the impurity concentration in the p-type impurity region 8 be set to 1×10¹⁹ cm⁻³ or higher. The resistance of the p-type impurity region 8 is thereby reduced to enable the electric field to be uniformly applied to the p-type impurity region 8. As a result, non-uniformities of the band and the multiplication factor in the surface can be further reduced.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2011-118766, filed on May 27, 2011 including specification, claims, drawings and summary, on which the Convention priority of the present application is based, are incorporated herein by reference in its entirety.

1. An avalanche photodiode comprising:
a semiconductor substrate of a first conductivity type;
an avalanche multiplication layer, an electric field control layer, a light absorption layer, and a window layer which are laid one on another in this order on a major surface of the semiconductor substrate;
an impurity region of a second conductivity type in a portion of the window layer; and
a straight electrode on the impurity region and connected to the impurity region, the straight electrode being straight as viewed in a plan view facing the major surface of the semiconductor substrate.

2. The avalanche photodiode according to claim 1, wherein distance between the straight electrode and an outer end of the impurity region does not exceed 30 μm.

3. The avalanche photodiode according to claim 1, wherein
the impurity region has one of a rectangular and corner-rounded rectangular shape, as viewed in the plan view,
the impurity region has longer sides and shorter sides, and
the straight electrode extends along one of the longer sides of the impurity region.

4. The avalanche photodiode according to claim 1, wherein the impurity region has a rectangular region, with longer sides and shorter sides, as viewed in the plan view, and includes two semicircular regions respectively joined to the shorter sides of the rectangular region.

5. The avalanche photodiode according to claim 4, further comprising semicircular electrodes on the semicircular regions and connected to the straight electrode.

6. The avalanche photodiode according to claim 1, further comprising light blocking metal on the window layer but not on the impurity region.

7. The avalanche photodiode according to claim 1, wherein the straight electrode comprises a plurality of straight electrode portions disposed in parallel with each other.

8. The avalanche photodiode according to claim 7, wherein distance between each of adjacent pairs of the plurality of straight electrode portions does not exceed 60 μm.

9. The avalanche photodiode according to claim 7, wherein the straight electrode has an electrode portion perpendicular to the plurality of straight electrode portions and connected in common to the plurality of straight electrode portions.

10. The avalanche photodiode according to claim 1, further comprising an electrode pad on a region of the window excluding the impurity region, wherein a connection portion between the straight electrode and the electrode pad extends over and across only one portion of the impurity region.

11. The avalanche photodiode according to claim 1, wherein the straight electrode comprises two portions.

12. The avalanche photodiode according to claim 11, further comprising
two electrode pads on regions of the window layer excluding the impurity region, and
connection portions between the two portions of the straight electrode, wherein the two electrode pads extend over and across only two portions of the impurity region.

13. The avalanche photodiode according to claim 1, wherein ratio of width of the straight electrode to width of the impurity region in a direction perpendicular to a direction in which the straight electrode extends is does not exceed 20 percent.

14. The avalanche photodiode according to claim 1, wherein the straight electrode has no angular corner portion.

15. The avalanche photodiode according to claim 1, wherein the straight electrode is transparent.

16. The avalanche photodiode according to claim 1, wherein an impurity concentration in the impurity region is at least 1×10¹⁹ cm⁻³.

17. An avalanche photodiode array comprising a plurality of avalanche photodiodes according to claim 1 which are disposed in an array.
